(19) United States
(12) Patent Application Publication
(10) Pub. No.: US 2015/0013608 A1
(43) Pub. Date: Jan. 15, 2015

(54) CERAMIC HEATER

(71) Applicant: Suncore Photovoltaics Incorporated, Irwindale, CA (US)

(72) Inventors: Peter Allen Zawadzki, Clinton, NJ (US); Sunil Vaid, North Brunswick, NJ (US); Gary D. Hering, Belle Mead, NJ (US); Mikhail Kats, Rockaway, NJ (US)

(21) Appl. No.: 13/940,543

(22) Filed: Jul. 12, 2013

(51) Int. Cl. C23C 16/48; C23C 16/32; C23C 16/34; H05B 3/14

(52) U.S. Cl. CPC C23C 16/481; H05B 3/141; C23C 16/325; C23C 16/34
USPC 118/725; 219/553; 219/541

(57) ABSTRACT

An electrically conductive ceramic heating element for use in a reactor for depositing a film of material onto a semiconductor wafer, said reactor comprising a reactor chamber, a radiative heating device disposed within the reactor chamber including the heating element and operative for heating said wafer to a temperature of greater than 1100 degrees C., a wafer carrier disposed within the reactor chamber and adjacent to the radiative heating device, the wafer carrier having at least one wafer cavity for supporting a semiconductor wafer for having a film of material be deposited thereon.

### FIELD OF THE INVENTION

The present disclosure relates in general to ceramic heater elements, and in particular ceramic heater elements for use in chemical vapor deposition reactors, and more particularly, to metal organic chemical vapor phase deposition reactors. In another aspect, the present disclosure relates to rotating wafer reactors incorporating a ceramic heating element, the reactor providing one or more gasses injected onto the surface of a rotating wafer carrier holding a wafer for growing various epitaxial layers and films thereon, and in particular, films of nitrides, such as gallium nitride.

### BACKGROUND OF THE INVENTION

Metal organic chemical vapor deposition (MOCVD) reactors have taken various forms, including horizontal reactors in which the wafer is mounted at an angle to the impinging process gases; horizontal reactors with planetary rotation in which the gases pass across the wafers; barrel reactors; and recently, vertical high-speed rotating disk reactors in which the gas or gases are injected downwardly onto a substrate surface which is rotating within a reactor. These types of MOCVD reactors have been found useful for wide varieties of epitaxial compounds, including various combinations of semiconductor single films and multilayered structures such as multijunction solar cells, semiconductor lasers and LEDs.

Deposition of certain materials such as nitride semiconductor material requires wafer temperature levels up to about 1200 degrees C. in a hydrogen, nitrogen, or ammonia environment with temperature uniformity of about +/−5.degree. C. during long deposition runs, e.g., up to 6-8 hours. Conventional radiant heating elements made of graphite cannot provide this temperature level especially in the above noted environments. Radiant heating elements made of tungsten or other refractory metal cannot provide temperature stability due to dimensional non-stability, i.e., warpage.

Vertical high speed MOCVD rotating disk epitaxial reactor technology has been known to provide ideal flow and thermal conditions for growth of these semiconductor materials. Reference may be made to U.S. Pat. No. 6,368, 404, which illustrates a typical or conventional reactor configuration using induction heating. Radiative heater reactors are similar in construction. Pancake-type radiative heating coils located below a susceptor in conventional reactors can provide uniform heating for the susceptor and wafer carrier.

For example, as shown in FIG. 2, derived from the above noted patent, a known MOCVD reactor includes a susceptor 103 connected for rotation to a spindle 142. The susceptor 103 is positioned overlying a pancake-type radiative heating device 104 in the nature of a spiral coil, such as shown in a top view in FIG. 1C. The radiative heating device 104 is generally the type known in the art which is suitable for heating the reaction chamber to a temperature up to about 1200 degrees C. in a hydrogen, nitrogen or ammonia environment as is required for the epitaxial deposition of a nitride material. In some embodiments, the wafer carrier 106 supporting multiple wafers 108 is removably positioned on the top surface of the susceptor 103. In other embodiments, a susceptor is not employed.

Dashed lines 110 in FIG. 2 schematically represent the heat flow created by the radiative heating device 104 to provide its heating. The wafer carrier 106 is accordingly heated by heat radiation from the radiative heating device 104.

Since heating elements made of tungsten or other refractory metals cannot provide temperature stability due to dimensional non-stability, i.e., warpage, and such dimensional changes results in different heating profiles, and different chemical reactions depending upon the position of the wafer, the composition of the deposited material on a wafer in a reactor may vary from wafer to wafer, or over the surface of a single wafer. Such variation is problematic from a high volume manufacturing standpoint, in which large quantities of substantial identical devices on a wafer, and from wafer to wafer, are desired.

Accordingly, there is an unsolved need for designing a heater element for a reactor for depositing, such as by chemical vapor deposition, a film of material, such as an epitaxial film of a nitride, onto a semiconductor wafer.

### SUMMARY OF THE INVENTION

### Objects of the Invention

It is an object of the present invention to provide a heating element for use in a reactor for depositing a film or material layer onto a wafer which is operative in a temperature range of up to about 1200 degrees C. for deposition of various materials such as epitaxial GaN.

Another object of the present invention is to provide radiative heated chemical vapor deposition reactor wherein the wafer carrier is uniformly heated.

Another object of the present invention is to provide chemical vapor deposition reactor which enables efficient heating of the wafer carrier.

Some implementations of the present disclosure may incorporate or implement fewer of the aspects and features noted in the foregoing objects.

### Features of the Invention

Briefly, and in general terms, the present disclosure provides a heating element for a chemical vapor deposition apparatus, comprising an electrically conductive ceramic element having a serpentine shape.

In some embodiments, the element has a circular periphery, with the element making a plurality of turns over the circular area bounded by the periphery.

In some embodiments, the element is between 1 and 10 mm in height, and between 10 and 40 mm in width, and between 500 and 5000 mm in length.

In some embodiments, the element has a rectangular or square cross-section.

In some embodiments, the element has electrical terminals at each end.

In some embodiments, the element is composed of titanium diboride or zirconium diboride.

In another aspect the present disclosure provides a heating element for a chemical vapor deposition apparatus, comprising a ceramic element composed of titanium diboride or zirconium diboride.

In another aspect the present disclosure provides a reactor for depositing a film of material onto a semiconductor wafer, said reactor comprising a reactor chamber, an radiative heating device disposed within the reactor chamber and operative for heating said wafer to a temperature of greater than 1100 degrees C., a wafer carrier disposed within the reactor chamber and adjacent to the radiative heating device, the wafer carrier having at least one wafer cavity for supporting a semiconductor wafer for having a film of material be deposited thereon.

In some embodiments, said wafer carrier is composed of graphite having a SiC coating.

In some embodiments, said wafer carrier has a thickness in the range of about ⅛ to about 1¼ inches.

In some embodiments, further comprising a susceptor is constructed from materials selected from the group consisting of graphite, tungsten and molybdenum for supporting the wafer carrier.

In some embodiments, said film of material is selected from the group consisting of SiC or GaN.

In some embodiments, said heating device is operative for heating said wafer to a temperature greater than 1100 degrees C.

In some embodiments, said heating device is operative for heating said wafer to a temperature of about 1200 degrees C. or more.

In some embodiments, said heating device comprises a ceramic element composed of titanium diboride or zirconium diboride.

In some embodiments, said heating device comprises an electrically conductive ceramic element having a serpentine shape.

In some embodiments, the element has a circular periphery.

In some embodiments, the element is between 1 and 10 mm in height, and between 10 and 40 mm in width, and between 500 and 5000 mm in length.

In some embodiments, the element has a rectangular or square cross-section.

In some embodiments, the reactor is an MOCVD reactor.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The above description, as well as further objects, features and advantages of the present invention will be more fully understood with reference to the following detailed description of a heated chemical vapor deposition reactor, when taken in conjunction with the accompanying drawings, wherein:

FIG. 1A is a diagrammatic illustration illustrating the construction of the ceramic heater element in accordance with one embodiment of a test structure of the present invention;

FIG. 1B is a cross-sectional view of the ceramic heater element of FIG. 1A through the 1B-1B plane in FIG. 1A in accordance with one embodiment of a test structure of the present invention;

FIG. 1C is a diagrammatic illustration illustrating the construction of the ceramic heater element in accordance with an embodiment of the present invention;

FIG. 2 is a diagrammatic cross-sectional illustration of a reactor for deposition of epitaxial films using a radiative heating device; and

FIG. 3 is a diagrammatic cross-sectional illustration of a reactor for depositing an epitaxial film of material onto a wafer in accordance with one embodiment of the present invention.

### DETAILED DESCRIPTION OF THE PREFERRED EMBODIMENTS

In describing the preferred embodiments of the subject matter illustrated and to be described with respect to the drawings, specific terminology will be resorted to for the sake of clarity. However, the invention is not intended to be limited to the specific terms so selected, and is to be understood that each specific term includes all technical equivalence which operate in a similar manner to accomplish a similar purpose.

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

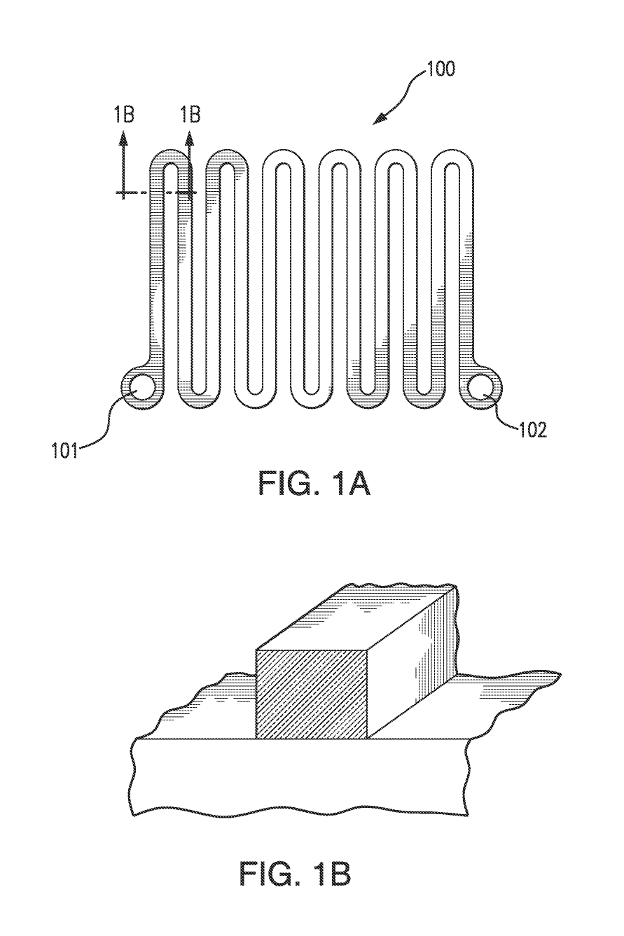

FIG. 1A is a diagrammatic illustration illustrating the construction of the ceramic heater element 100 in accordance with one embodiment of a test structure of the present invention. In this embodiment, the electrically conductive ceramic element has a serpentine shape that winds over a square surface. In some embodiments, the element has a rectangular or square cross-section.

In some embodiments, the element has electrical terminals 101 and 102 at each end for receiving a DC current.

In some embodiments, the element is composed of an electrically conductive ceramic material such as titanium diboride or zirconium diboride.

FIG. 1B is a cross-sectional view of the ceramic heater element of FIG. 1A through the 1B-1B plane in FIG. 1A in accordance with one embodiment of a test structure of the present invention. In some embodiments, the element is between 1 and 10 mm in height, and between 10 and 40 mm in width, and between 500 and 5000 mm in length. In some embodiments, the element is 6 mm in height, 23 mm in width, and 386 mm in length.

FIG. 1C is a diagrammatic illustration illustrating the construction of the ceramic heater element 200 in accordance with an embodiment of the present invention. In the illustrated embodiment, the element has a circular periphery, with the element making a plurality of turns over the circular area bounded by the periphery, with electrical terminals 201 and 202 at each end of the serpentine structure for providing an electrical current to flow through the heater element.

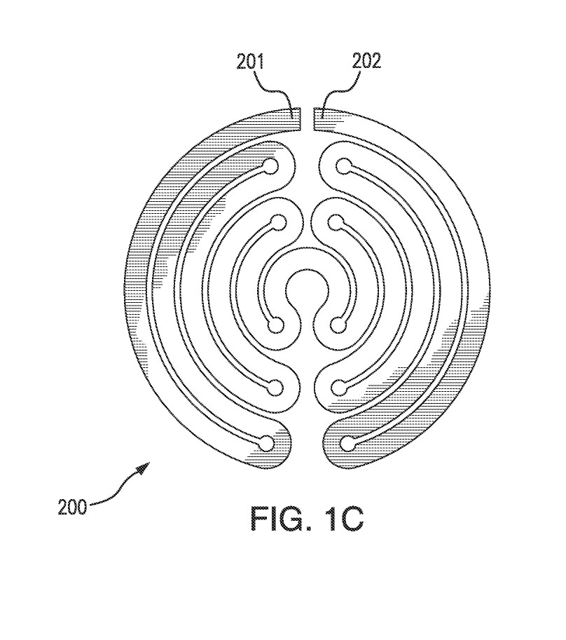

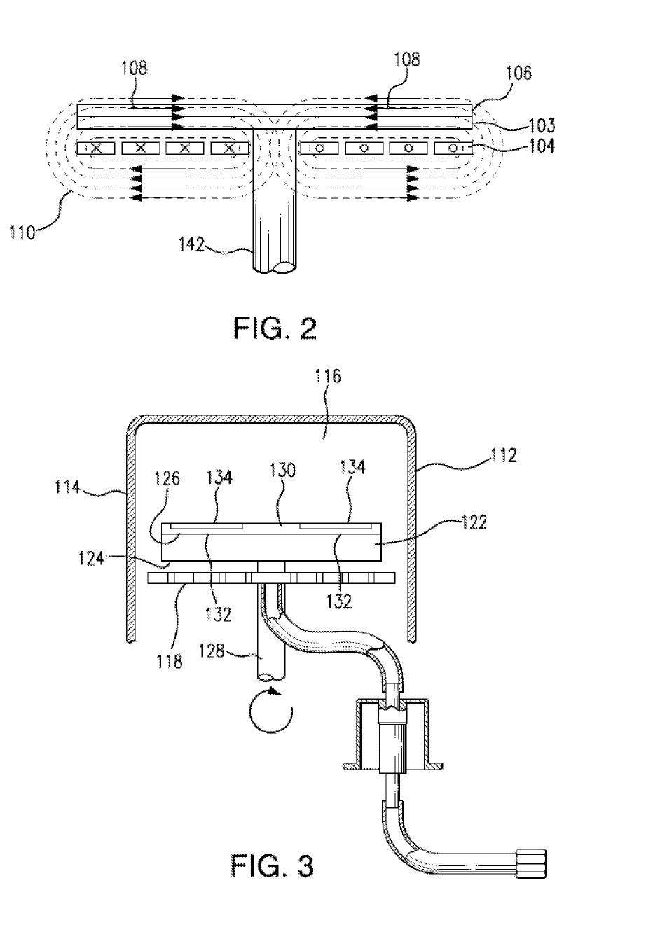

Referring now to FIGS. 2 and 3, there is schematically illustrated a reactor generally designated by reference numeral 112 specifically suitable for depositing an epitaxial film of material onto a wafer. The reactor 112 includes a housing 114 which defines a reactor chamber 116. Positioned within the reactor chamber 116 is a pancake-type radiative heating device 118. In other embodiments, the heating device 118 may be designed as a radio frequency induction coil of the type known for use in chemical vapor deposition reactors. In some embodiments, a susceptor 122 may be positioned overlying the heating device 118. The susceptor 122 has a bottom surface 124 facing the heating device 118 and a top surface 126 facing away from the heating device. The susceptor 122 is mounted to a spindle 128 which is operative for rotation of the susceptor during the chemical vapor deposition process. The housing 114 is provided with a closable opening (not shown) which enables access to the reactor chamber 116 for positioning a wafer carrier 130 onto the top surface 126 of the susceptor 122. The wafer carrier 130 is provided with one or more recessed portions 132 operative for receiving a wafer 134. The construction of the recessed portions 132 are such that the top surface of the wafer 134 is generally flush with the top surface of the wafer carrier 130.

The aforementioned components of the reactor 112 for chemical vapor deposition are generally well known in the art. For example, chemical vapor deposition reactors such as MOCVD reactors were designed and developed by Emcore Corporation, now located in Albuquerque, New Mexico. In general, the reactor 112 of this type is operative for the chemical vapor deposition of an epitaxial layer of material onto the surface of wafers 134 during operation of the reactor. A variety of film materials may be epitaxially grown on the wafers 134, for example, silicon carbide, gallium nitride, gallium arsenide, indium gallium arsenide, aluminum gallium arsenide and the like. Specific processes for forming epitaxial layers from the aforementioned materials are likewise well known in the art. For example, general reference is made to U.S. Pat. No. 5,835,678, which patent was originally assigned to Emcore Corporation and whose disclosure is incorporated herein by reference. Accordingly, a further description of the general construction of a chemical vapor deposition reactor 112, and more particularly a MOCVD reactor, as well as its operation in epitaxial growth of various materials from precursor materials will not be further described.

Although the invention herein has been described with reference to particular embodiments, it is to be understood that the embodiments are merely illustrative of the principles and application of the present invention. It is therefore to be understood that numerous modifications may be made to the embodiments and that other arrangements may be devised without departing from the spirit and scope of the present invention as defined by the claims.

1. A heating element for a chemical vapor deposition apparatus, comprising an electrically conductive ceramic element having a serpentine shape.

2. A heating element as defined in claim 1, wherein the element has a circular periphery, with the element making a plurality of turns over the circular area bounded by the periphery.

3. A heating element as defined in claim 1, wherein the element is between 1 and 10 mm in height, and between 10 and 40 mm in width, and between 500 and 5000 mm in length.

4. A heating element as defined in claim 1, wherein the element has a rectangular or square cross-section.

5. A heating element as defined in claim 1, wherein the element has electrical terminals at each end for receiving a DC current.

6. A heating element as defined in claim 1, wherein the element is composed of titanium diboride or zirconium diboride.

7. A heating element for a chemical vapor deposition apparatus, comprising a conductive ceramic element.

8. A reactor for depositing a film of material onto a semiconductor wafer, said reactor comprising a reactor chamber, an radiative heating device disposed within the reactor chamber and operative for heating said wafer to a temperature of greater than 1100 degrees C., a wafer carrier disposed within the reactor chamber and adjacent to the heating device, the wafer carrier having at least one wafer cavity for supporting a semiconductor wafer for having a film of material be deposited thereon.

9. The reactor as defined in claim of claim 8, wherein said wafer carrier is constructed of graphite having a SiC coating.

10. The reactor as defined in claim of claim 8, wherein said wafer carrier has a thickness in the range of about ⅛ to about 1¼ inches.

11. The reactor as defined in claim of claim 8, further comprising a susceptor is constructed from materials selected from the group consisting of graphite, tungsten and molybdenum for supporting the wafer carrier.

12. The reactor as defined in claim of claim 8, wherein said film of material is selected from the group consisting of SiC or GaN.

13. The reactor as defined in claim of claim 8, wherein said heating device is operative for heating said wafer to a temperature greater than 1200 degrees C.

14. The reactor as defined in claim of claim 8, wherein said heating device is operative for heating said wafer to a temperature of about 1100 to 1200 degrees C.

15. The reactor as defined in claim of claim 8, wherein said heating device comprises a ceramic element composed of titanium diboride or zirconium diboride.

16. The reactor as defined in claim of claim 8 wherein said heating device comprises an electrically conductive ceramic element having a serpentine shape.

17. The reactor as defined in claim of claim 16, wherein the element has a circular periphery.

18. The reactor as defined in claim of claim 16, wherein the element is between 1 and 10 mm in height, and between 10 and 40 mm in width, and between 500 and 5000 mm in length.

19. The reactor as defined in claim of claim 16, wherein the element has a rectangular or square cross-section.

20. The reactor as defined in claim of claim 8, wherein the reactor is an MOCVD reactor.
